(19) United States
(12) Patent Application Publication
(10) Pub. No.: US 2022/0035962 A1
(43) Pub. Date: Feb. 3, 2022

(54) Building design method, device, system and storage medium

(71) Applicant: Shenzhen XKool Technology CO., Ltd., Shenzhen (CN)

(72) Inventors: Wanyu He, Shenzhen (CN); Xin Zhong, Shenzhen (CN)

(21) Appl. No.: 17/450,992

(22) Filed: Oct. 14, 2021

(51) Int. Cl. G06F 30/13; G06Q 50/16

(52) U.S. Cl. CPC G06F 30/13; G06Q 50/165

(57) ABSTRACT

A building design method, device, system and storage medium, which obtains the location information of the target cadastral land parcel, and based on such location information, obtains peripheral information of the target cadastral land parcel such as the economy information, community information and transportation information, and based on such economy information, community information and transportation information, controls the cadastral land parcel evaluating device to generate multiple data models of the target cadastral land parcel; such multiple data models comprise economic vitality model, economic value model, noise analysis model and viewshed analysis model, then obtains the indicator data of the target cadastral land parcel such as floor area ratio, land area, city, land usage, functional composition, and the building density, and finally controls the scheme generating device to generate multiple building design schemes based on the data model and the indicator data.

### TECHNICAL FIELD

The present disclosure relates to the technical field of building design, specifically relates to a building design method, device, system and storage medium.

### BACKGROUND

When real estate developers are planning building construction, currently, the building design method in the prior art: the marketing and planning department proposes real estate product requirements and potential product composition, next, designers create building design concept, make and output drawings using building design relevant software based on the planning requirements.

Conventional building design software comes in simple functionality and configuration and is only a laborious design tool to building designers, whereas current building design work involves multi-side interaction and information sharing, conventional building design software cannot provide quick and accurate design scheme for users, but rather require repetitive operation for architectural designers. For example, designers generally adopt Computer-Aided Design (CAD) method to design buildings, designers generally begin to design starting from sketch, during the course of design, designers generally use computer to perform huge amount of computation, analysis and modification, to form optimum design scheme finally.

However, this design method has many disadvantages. In the course of designing, generally, developers propose requirements, next, designers adjust and feed back repeatedly, consuming a large amount of time and energy, thus the efficiency is low, but the client's requirements may not be satisfied yet; the design scheme finally obtained may have problems of unreasonable design, the need of huge modification and high time consumption etc. due to inaccurate requirement provided by the real estate developers.

### SUMMARY

The present disclosure provides a building design method, device, system and storage medium, in a bid to solve the problem of low efficiency in obtaining building design scheme and possible failure to meet requirements in the course of building design.

A building design method used in building design system, the building design system comprises cadastral land parcel evaluating device and scheme generating device, the method comprises:

obtaining the location information of the target cadastral land parcel, and obtaining the peripheral information of the target cadastral land parcel based on the location information, the peripheral information comprises economy information, community information and transportation information;

based on the economy information, community information and transportation information, controlling the cadastral land parcel evaluating device to generate multiple data models of the target cadastral land parcel. The multiple data models comprise economic vitality model, economic value model, noise analysis model and viewshed analysis model;

obtaining the indicator data of the target cadastral land parcel, the indicator data comprise floor area ratio, land area, city, land usage, functional composition and building density;

controlling the scheme generating device to generate multiple building design schemes based on the data models and the indicator data.

Further, after controlling the scheme generating device to generate multiple building design schemes based on the data models and the indicator data, the method further comprises:

obtaining user demand instruction, and determine the target design scheme from the multiple building design schemes based on the user demand instruction;

determining the display category of the target design scheme, and displaying the corresponding design content of the target design scheme based on the display category.

Further, the acquisition of the indicator data of the target cadastral land parcel, it further comprises:

obtaining the preset indicator data input by user;

obtaining the building design specification data of the city where the cadastral land parcel is located;

obtaining the indicator data by comparing the preset indicator data with the building design specification data.

Further, the multiple building design schemes comprise:

an optimum scheme, of which the floor area ratio indicator, the density indicator, profit indicator and value indicator are the closest to the corresponding indicators of the indicator data among all schemes;

an optimum floor area ratio scheme, of which the floor area ratio is the closest to the floor area ratio corresponding to the indicator data among all schemes;

a maximum value scheme, of which the sales volume is the highest among all schemes;

a maximum profit scheme, of which the profit amount is the highest among all schemes;

a high-low configuration scheme, which has configuration of high-rise buildings and multi-floor buildings or villa among all schemes;

an ordinary layout scheme, of which the floor area ratio satisfies the floor area ratio corresponding to the indicator data, and of which the layout between the buildings is arranged from the most outside to the inside spirally based on the outline of the target cadastral land parcel;

a qualified floor area ratio scheme, of which the floor area ratio satisfies the floor area ratio corresponding to the indicator data and of which the layout spacing between the buildings are the most distant among all schemes;

a multi-side layout scheme, of which the floor area ratio satisfies the floor area ratio corresponding to the indicator data and of which the buildings are sequentially arranged from outside to inside firstly based on the outline of the cadastral land parcel among all schemes;

a building greening rate scheme, of which the floor area ratio satisfies the floor area ratio corresponding to the indicator data and which is the closest to the greening rate corresponding to the indicator data among all schemes.

Further, after controlling the design device to generate multiple building design schemes based on the data models and the indicator data, the method further comprises:

determining a building design scheme from the multiple building design schemes as the target design scheme, and obtaining at least one comparison design scheme;

comparing and displaying based on the target design scheme and the comparison design scheme.

Further, after comparing and displaying based on the target design scheme and the comparison design scheme, it further comprises:

conducting comparison based on the target design scheme and the comparison design scheme;

displaying the location information and current condition information of the target cadastral land parcel;

displaying pictures of the peripheral support facilities of the target cadastral land parcel based on the peripheral information of the target cadastral land parcel;

generating aerial view of design of the target cadastral land parcel based on the target design scheme and the peripheral information.

A building design device used in building design system, the building design system comprises cadastral land parcel evaluating device and scheme generating device, and the building design device comprises:

a first acquisition module, to obtain the location information of the target cadastral land parcel, and obtain the peripheral information of the target cadastral land parcel based on the location information, the peripheral information comprises economy information, community information and transportation information;

a first generation module, to control the cadastral land parcel evaluating device to generate multiple data models of the target cadastral land parcel based on the economy information, community information and transportation information. The multiple data models comprise economic vitality model, economic value model, noise analysis model and viewshed analysis model;

a second acquisition module, to obtain the indicator data of the target cadastral land parcel, the indicator data comprise floor area ratio, land area, city, land usage, functional composition and building density;

a second generation module, to control the scheme generating device to generate multiple building design schemes based on the data models and the indicator data.

a building design device, comprising memory, processor and computer program stored in the memory and runnable in the processor, wherein the steps of the building design method described above are realized when the processor executes the computer program.

a building design system, comprising cadastral land parcel evaluating device, scheme generating device and the building design device described above.

A readable storage medium storing computer program, wherein the steps of the building design method described above are implemented when the computer program is executed by the processor.

In respect of the building design method, device, system and storage medium described above, the building design method is used in the building design system, the building design system comprises cadastral land parcel evaluating device and scheme generating device, the method obtains the location information of the target cadastral land parcel, and based on such location information, obtains peripheral information of the target cadastral land parcel such as the economy information, community information and transportation information, and then based on such economy information, community information and transportation information, controls the cadastral land parcel evaluating device to generate multiple data models of the target cadastral land parcel (such multiple data models comprise economic vitality model, economic value model, noise analysis model and viewshed analysis model), then obtains the indicator data of the target cadastral land parcel such as floor area ratio, land area, city, land usage, functional composition, and the building density, and finally controls the scheme generating device to generate multiple building design schemes based on the data model and the indicator data. The present disclosure generates multiple data models of the target cadastral land parcel by obtaining the peripheral information of the target cadastral land parcel based on the location of the target cadastral land parcel, and further generates multiple building design schemes based on the data models and the indicator data of the target cadastral land parcel input by the user, realizing digitalization of building design scheme generation of the target cadastral land parcel, shortening overall scheme design time, saving users from specific collection and screening of relevant data required for designing the building design scheme, not only reducing the possibility of modification of the building design scheme due to change of data in the design process, improving the efficiency of obtaining building design scheme, but also increasing the diversity of the building design schemes to satisfy the demands of the parties.

### BRIEF DESCRIPTION OF THE DRAWINGS

In order to describe the technical solutions of the embodiments of the present disclosure, below is simple introduction to the figures used in the embodiment description of the present disclosure. Apparently, the figures described below are only some embodiments of the present disclosure, for those of ordinary skill in the art, other figures can also be obtained based on these figures without contribution of creative work.

FIG. 1 is the schematic of the structure of the building design system in one embodiment of the present disclosure;

FIG. 2 is the schematic flow chart of the building design method in one embodiment of the present disclosure;

FIG. 3 is another schematic flow chart of the building design method in one embodiment of the present disclosure;

FIG. 4 is schematic of the structure of the building design device in one embodiment of the present disclosure;

FIG. 5 is another schematic of the structure of the building design device in one embodiment of the present disclosure.

### DESCRIPTION OF THE EMBODIMENTS

Below is clear and complete description of the technical solutions in the embodiments of the present disclosure in conjunction with the figures of such embodiments, apparently, the embodiments described are some embodiments of the present disclosure only rather than all embodiments. Any other embodiment obtained by those of ordinary skill in the art based on the embodiments of the present disclosure without contribution of creative work is also within the protective scope of the present disclosure.

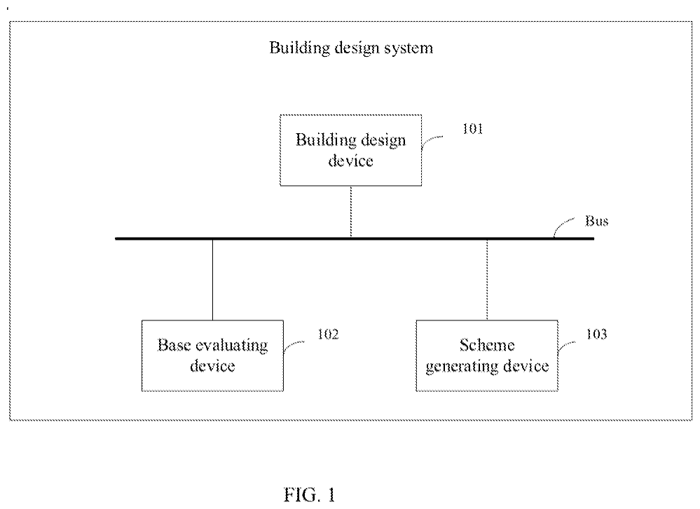

A building design method provided in the embodiment of the present disclosure, which can be applied in the building design system as shown in FIG. 1. The building design system comprises building design device 101, cadastral land parcel evaluating device 102 and scheme generating device 103, where, the building design device 101, the cadastral land parcel evaluating device 102 and the scheme generating device 103 communicate with each other through buses. The building design system can be implemented through independent server or cluster of multiple servers.

In one embodiment, the building design system further comprises enterprise management device 104, which primarily comprises 5 major modules: a data statistics, a department management, a member management, a project management and a building type management.

The data statistics module: helps enterprise provide data of all schemes during the course of employee's use of small library platform, and provides such data to users in a multi-dimensional way as the basis for management.

The department management module: provides enterprise with department permission classification and management.

The member management module: provides enterprise with employee permission management and classification.

The project management module: provides enterprise with project management and review.

The building type management module: provides enterprise with building type management and classification, helps enterprise realize standardized building type management.

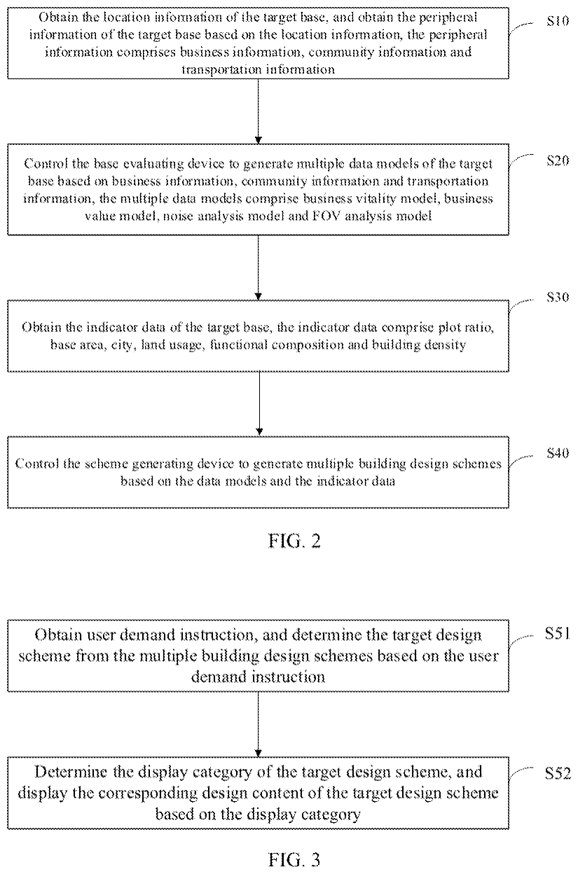

In one embodiment, as shown in FIG. 2, a building design method is provided, and by taking the method applied in the building design device in FIG. 1 as an example for description, it comprises the following steps:

S10: Obtain the location information of the target cadastral land parcel, and obtain the peripheral information of the target cadastral land parcel based on the location information, the peripheral information comprises economy information, community information and transportation information.

Before designing the scheme, user can select the location of the target cadastral land parcel as one likes, after obtaining the location information of the target cadastral land parcel input by the user, the building design device further obtains the peripheral information in the preset distance scope of the target cadastral land parcel centered on the target cadastral land parcel, the main peripheral information of the target cadastral land parcel obtained comprises economy information, community information and transportation information.

In other embodiments, the peripheral information of the target cadastral land parcel comprises information on peripheral facilities such as education information, medical information, government information and landscape information.

Where, the method for obtaining the peripheral information of the target cadastral land parcel is: take the target cadastral land parcel as the center, capture real time data on the peripheral facilities of the target cadastral land parcel through APIs provided by third party map service providers, as well as third party websites such as municipal government websites and real estate websites, and then filter and analyze such real time data captured.

For example, the obtained location information of the target cadastral land parcel input by user is residential quarter A of Shenzhen City, take residential quarter A of Shenzhen City as the center, obtain relevant peripheral information in the 1.5 km peripheral scope centered on residential quarter A of Shenzhen City, the main peripheral information of the target cadastral land parcel obtained comprises economy information, community information and transportation information.

In this embodiment, the preset distance 1.5 km is only exemplary, in other embodiments, the preset distance can be other values which will not be further described herein.

After obtaining the peripheral information of the target cadastral land parcel based on the location, the method further comprises: categorize the peripheral information; obtain category instruction, display all buildings corresponding to the peripheral information category per the category instruction; obtain building display instruction, display information on the corresponding building per the building display instruction.

For example, take residential quarter A of Shenzhen City as the center, after obtaining relevant peripheral information in the 1.5 km peripheral scope centered on residential quarter A of Shenzhen City, categorize the peripheral information, e.g., economy, education, medical, government, landscape, community and transportation; obtain the category instruction input by user, display all buildings corresponding to the peripheral information category per the category instruction, for example, if the user inputs economy instruction, all commercial buildings in 1.5 kin peripheral scope of residential quarter A of Shenzhen City will be displayed per the economy instruction; obtain the building display instruction input by the user, display information on corresponding building per the building display instruction, for example, obtain the building a display instruction input by the user, and display the basic information on building a per the building an information display instruction.

S20: control the cadastral land parcel evaluating device to generate multiple data models of the target cadastral land parcel based on economy information, community information and transportation information, and the multiple data models comprise economic vitality model, economic value model, noise analysis model and viewshed analysis model.

After obtaining the peripheral information of the target cadastral land parcel based on the location information, extract relevant data on roads, building heights, functional category, residential population etc., then filter and recombine such relevant data on roads, building heights, functional category, residential population etc., control the cadastral land parcel evaluating device to generate multiple data models of the target cadastral land parcel, where, such multiple data models comprise economic vitality model, economic value model, noise analysis model and viewshed analysis model.

Now, it is assumed that user has completed one-stop collection and analysis of early stage data of the target cadastral land parcel for building design.

S30: obtain indicator data of the target cadastral land parcel, comprising floor area ratio, land area, city, land usage, functional composition and building density.

After obtaining the peripheral information and data models of the target cadastral land parcel, obtain the indicator data corresponding to the building design scheme of the target cadastral land parcel, comprising relevant indicator data such as floor area ratio, land area, city, land usage, functional composition and building density.

Wherein the corresponding indicator values of the indicator data shall accord with normal value range. For example, if the target cadastral land parcel is used for residential plan, then the floor area ratio of the indicator data shall satisfy the floor area ration requirement of normal residential buildings.

In another embodiment, after obtaining the peripheral information and data models of the target cadastral land parcel, in step S30, i.e., obtaining the indicator data of the target cadastral land parcel, it specifically comprises steps as follow:

S31: obtain the preset indicator data input by user;

After obtaining the peripheral information and data models of the target cadastral land parcel, obtain the preset indicator data of the building design scheme of the target cadastral land parcel, where, the preset indicator data comprise relevant indicator data such as floor area ratio, land area, city, land usage, functional composition and building density.

S32: obtain the building design specification data of the city;

After obtaining the preset indicator data input by user, obtain the building design specification data of the city based on the city where the target cadastral land parcel is located.

For example, if the target cadastral land parcel is located in Shenzhen, then obtain the building design specification data of Shenzhen City.

S33: obtain the indicator data by comparing the preset indicator data with the building design specification data.

After obtaining the building design specification data of the city, compare the preset indicator data based on the building design specification data obtained to obtain the indicator data of the target cadastral land parcel.

Where, if the preset indicator data are in the scope of the indicator data corresponding to the building design specification data of Shenzhen City, then take the preset indicator data as the indicator data of the target cadastral land parcel; if the preset indicator data are beyond the scope of the indicator data corresponding to the building design specification data of Shenzhen City, then take the indicator data corresponding to the building design specification data of Shenzhen City as the indicator data of the target cadastral land parcel.

In this embodiment, by obtaining the preset indicator data input by user, then obtaining the building design specification data of the city, and comparing the preset indicator data with the building design specification data, finally obtain the indicator data, ensuring the compliance and accuracy of the indicator data of the target cadastral land parcel, hence improving the rationality and compliance of the building design scheme, not only reducing the problem of implementation failure due to non-compliance of building design scheme, but also reducing the time consumed in scheme modification due to non-compliance of building design scheme, improving efficiency.

S40: control the scheme generating device to generate multiple building design schemes based on the data models and the indicator data.

After obtaining the indicator data of the target cadastral land parcel such as floor area ratio, land area, city, land usage, functional composition and building density, control the scheme generating device to generate multiple building design schemes based on the obtained data models and indicator data of the target cadastral land parcel.

Where, the building design schemes comprise at least the maximum value scheme, the maximum building density scheme and the maximum profit scheme.

The maximum value scheme means the scheme with the highest sale price, for example, when the sale price input by user is 10,000 yuan/m², calculate the building scheme with the highest total sale price based on the selected conditions.

The maximum building density scheme means the scheme with the calculated maximum density in compliance with the building layout density (e.g., firefighting specification).

The maximum profit scheme means the scheme with the highest calculated profit based on the sale price and cost information input by the user.

In this embodiment, the sale price and building density are only exemplary, in other embodiments, the sale price and building density can be other values which will not be further described herein.

In another embodiment, the multiple building design schemes further comprise:

An optimum scheme, of which the floor area ratio indicator, the density indicator, profit indicator and value indicator are the closest to the corresponding indicators of the indicator data among all schemes.

An optimum floor area ratio scheme, of which the floor area ratio is the closest to the floor area ratio corresponding to the indicator data among all schemes.

For example, the preset floor area ratio value input by the user before generating building design scheme is 2.0, whereas in the generated building design schemes, the relevant values comprise 1.987, 1.991, 1.968 and 1.999, the building design device will automatically select the scheme with floor area ratio 1.999 as the optimum floor area ratio scheme, masking schemes with other floor area ratios.

A high-low configuration scheme, which has configuration of high-rise buildings and multi-floor buildings or villa among all schemes.

An ordinary layout scheme, of which the floor area ratio satisfies the floor area ratio corresponding to the indicator data, and of which the layout between the buildings is arranged from the most outside to the inside spirally based on the outline of the target cadastral land parcel.

Namely, under the precondition of satisfying floor area ratio, in this scheme, the layout between the buildings is arranged from the most outside to the inside spirally based on the outline shape of the cadastral land parcel.

A qualified floor area ratio scheme, of which the floor area ratio satisfies the floor area ratio corresponding to the indicator data and of which the layout spacing between the buildings are the most distant among all schemes.

A multi-side layout scheme, of which the floor area ratio satisfies the floor area ratio corresponding to the indicator data and of which the buildings are sequentially arranged from outside to inside firstly based on the outline of the cadastral land parcel among all schemes.

Namely, under the precondition of satisfying the floor area ratio, in this scheme, buildings are laid out along the cadastral land parcel first until all sides of the cadastral land parcel are placed with buildings before placing buildings towards the inside of the cadastral land parcel.

A building greening rate scheme, of which the floor area ratio complies with the floor area ratio corresponding to the indicator data and which is the closest to the greening rate corresponding to the indicator data among all schemes.

For example, the preset greening rate value input by the user before generating building design scheme is 30%, whereas in the generated building design schemes, the relevant greening rate values comprise 28.28%, 29.78%, 29.98% and 29.99%, the system will automatically select the scheme with greening rate 29.99% as the building greening rate scheme, masking schemes with other greening rates.

When designing residential building scheme, it may be required to provide building design schemes with maximum value, maximum building density and maximum profit, and conventional solution is calculation using Excel worksheet, which consumes much time and energy. With the smart measurement and calculation using the building design method provided in the present disclosure, user just needs to input corresponding indicator data to obtain the indicator content, facilitating user's measurement and planning before purchasing a parcel.

In the prior art, when designing a scheme, designers (users) can only rely on relevant software and edit by themselves, the design process is slow and consumes huge amount of labor. With the building design method in the present disclosure, after obtaining the peripheral information and data models of the target cadastral land parcel quickly, by inputting the preset indicator data of the target cadastral land parcel, user can obtain various building design schemes just at one click, convenient and efficient.

In this embodiment, through obtaining the location information of the target cadastral land parcel, and based on such location information, obtain peripheral information of the target cadastral land parcel such as the economy information, community information and transportation information, and then based on such economy information, community information and transportation information, control the cadastral land parcel evaluating device to generate multiple data models of the target cadastral land parcel; such multiple data models comprise economic vitality model, economic value model, noise analysis model and viewshed analysis model, then obtain the indicator data of the target cadastral land parcel such as floor area ratio, land area, city, land usage, functional composition, and the building density, and finally control the scheme generating device to generate multiple building design schemes based on the data model and the indicator data. The present disclosure generates multiple data models of the target cadastral land parcel by obtaining the peripheral information of the target cadastral land parcel based on the location of the target cadastral land parcel, and further generates multiple building design schemes based on the data models and the indicator data of the target cadastral land parcel input by the user, realizing digitalization of building design scheme generation of the target cadastral land parcel, shortening overall scheme design time, saving users from specific collection and screening of relevant data required for designing the building design scheme, not only reducing the possibility of modification of the building design scheme due to change of data in the design process, improving the efficiency of obtaining building design scheme, but also increasing the diversity of the building design schemes to satisfy the demands of the parties.

In one embodiment, as shown in FIG. 3, after step S40, i.e., after controlling the scheme generating device to generate multiple building design schemes based on the data models and the indicator data, the method further specifically comprises steps as follow:

S51: obtain user demand instruction, and determine the target design scheme from the multiple building design schemes based on the user demand instruction.

After controlling the scheme generating device to generate multiple building design schemes based on the data models and the indicator data, obtain the user demand instruction input by the user, and determine the target design scheme from multiple building design schemes per the user demand instruction.

For example, the multiple building design schemes comprise maximum value scheme, maximum building density scheme and maximum profit scheme, if the user selects the maximum value scheme by clicking mouse, the maximum value scheme will be determined as the target design scheme.

In this embodiment, the mouse click as the user demand instruction input by user is only exemplary, in other embodiments, the user demand instruction can be other implementations, which will not be further described herein.

S52: determine the display category of the target design scheme, and display the corresponding design content of the target design scheme based on the display category.

After determining the target design scheme from the multiple building design schemes per user demand instruction, determine the display category of the target design scheme, and display the corresponding design content of the target design scheme based on the display category. Where, the display categories of the target design scheme comprise: Excel, sunlight mapping, unit distribution, building information models, CAD, HD pictures.

For example, after determining the maximum value scheme as the target design scheme, determine the display category of the maximum value scheme as Excel, then display the content of the maximum value scheme in the form of Excel; after determining the maximum building density scheme as the target design scheme, determine the display category of the maximum building density scheme as CAD, then display the content of the maximum building density scheme in the form of CAD.

In this embodiment, control the scheme generating device to generate multiple building design schemes based on data models and indicator data, obtain user demand instruction, determine the target design scheme from the multiple building design schemes per the user demand instruction, then determine the display category of the target design scheme, and display the design content corresponding to the target design scheme based on the display category, allowing users to select target design scheme based on their demands and display the design scheme in different display categories as they like, making the display of the target design scheme more convenient and intuitive.

In one embodiment, after step S40, i.e., after controlling the scheme generating device to generate multiple building design schemes based on the data models and the indicator data, the method further specifically comprises steps as follow:

S61: determine a building design scheme from the multiple building design schemes as the target design scheme, and obtain at least one comparison design scheme.

After controlling the scheme generating device to generate multiple building design schemes based on the data models and the indicator data, determine one building design scheme as the target design scheme from multiple building design schemes, and obtain at least one comparison design scheme.

For example, take the maximum profit scheme as the target design scheme, and take the maximum value scheme as the comparison design scheme for the maximum profit scheme.

The maximum value scheme means the scheme with the highest sale price, for example, when the sale price input by user is 10,000 yuan/m², calculate the building scheme with the highest total sale price based on the selected conditions.

The maximum building density scheme means the scheme with the calculated maximum density in compliance with the building layout density (e.g., firefighting specification).

The maximum profit scheme means the scheme with the highest calculated profit based on the sale price and cost information input by the user.

S62: compare and display based on the target design scheme and the comparison design scheme.

After selecting the target design scheme and the comparison design scheme, compare and display the target design scheme and the comparison design scheme based on the information of the target cadastral land parcel and the design content of the design scheme.

Where, after comparing and displaying based on the target design scheme and the comparison design scheme, it specifically comprises steps as follow:

S621: conduct comparison based on the target design scheme and the comparison design scheme;

After selecting the target design scheme and the comparison design scheme, conduct pairwise comparison of the design contents of the target design scheme and the comparison design scheme.

For example, take the maximum profit scheme as the target design scheme, and take the maximum value scheme as the comparison design scheme for the maximum profit scheme, compare the difference between the maximum profit scheme and the maximum value scheme, display the advantages of the maximum profit scheme.

In this embodiment, comparing the difference between the maximum profit scheme and the maximum value scheme and displaying the advantages of the maximum profit scheme are only exemplary, and in other embodiments, comparing the design contents of the target design scheme and the comparison design scheme can have other implementations, which will not be further described herein.

S622: display the location information and current condition information of the target cadastral land parcel.

Obtain and display the location information and current condition information of the target cadastral land parcel.

Where, the location information is relevant geographic information of the city where the target cadastral land parcel is located, and the current condition information of the cadastral land parcel is user's text introduction of the area where the target cadastral land parcel is located.

For example, the city where the target cadastral land parcel is located is Shenzhen;

Location information: Shenzhen is located in south China coast, of which the land area is 1996.85 sq.km., neighboring Hong Kong, located in the south of Guangdong Province and the east bank of the Pearl River, to the east is Daya Bay and Dapeng Bay, to the west is the Pearl River Estuary and Lingdingyang Estuary; to the south is Hong Kong neighboring the Shenzhen River, to the north is the two neighboring cities Dongguan and Huizhou. Its vast sea area connects the South China Sea and the Pacific Ocean. Shenzhen is located to the south of the Tropic of Cancer, extending from east longitude 113°46′ to 114°37′ and from north latitude 22°27′ to 22°52′. In 2016, the permanent resident population is 11.9084 million.

For example, the target cadastral land parcel is located in Futian District of Shenzhen City;

The current condition information of the cadastral land parcel: Futian District is in Shenzhen City, Guangdong Province, a downtown area of Shenzhen, where the Municipal Party Committee and the Municipal Government are located. It is in the central part of Shenzhen, starting from Hongling Road in the east connecting with Luohu District to Qiaocheng Road (E) and Haiyuan Road One in the west connecting with Nanshan District, close to Shenzhen River and Shenzhen Bay in the south overlooking MaiPo and Yuen Long of New Territories, Hong Kong, to Baimeishi, Danaoke and Huangzuyuan ridges etc. in the north, neighboring Minzhi Sub-District of Longhua District. The total land area of Futian District is 78.8 sq.km., primarily consisting of the downtown area and the belt-shaped economic development zones at the two sides of Shennan Avenue, as well as some hills, mountain lands and beaches, the terrain is high in the north and low in the south, located to the south of the Tropic of Cancer, a sub-tropical maritime climate. As of 2016, there were 10 sub-districts in Futian District; in 2016, the permanent resident population according to statistics in Futian District was 1.5017 million, the gross regional domestic product realized was 356.144 billion yuan, the per capita gross regional product was 242,100 yuan.

S623: display pictures of the peripheral support facilities of the target cadastral land parcel based on the peripheral information of the target cadastral land parcel.

Display pictures of the peripheral support facilities of the target cadastral land parcel based on the peripheral information of the target cadastral land parcel, where, the peripheral support facilities comprise water resources, green lands, roads, education, transportation, medical health and community, display information on water resources, green lands, roads, education, transportation, medical health and community etc. in the form of map pictures.

S624: generate aerial view of design of the target cadastral land parcel based on the target design scheme and the peripheral information.

For example, if take the maximum building density scheme as the target design scheme, then generate a design aerial view of the target cadastral land parcel using the contents generated based on the peripheral information and the maximum building density scheme of the target cadastral land parcel.

After completing the design of the building design scheme, user needs to interpret the design content of the building design scheme to the client for bidding, conventionally, the way of interpretation is to edit the building design scheme into PPT for interpretation for bidding, in consideration of this application scenario, the building design method disclosed in the present disclosure further provides feature of scheme comparison, which allows to export the content of the building design scheme to generate PPT directly.

In the embodiment, determine a building design scheme as the target design scheme from multiple building design schemes, and obtain at least one comparison design scheme to conduct comparison between the target design scheme and the comparison design scheme, allowing user to more intuitively feel the advantages of the target design scheme, and more conveniently understand and display the design content of the target design scheme, easy and swift.

In one embodiment, after controlling the scheme generating device to generate multiple building design schemes based on the data models and the indicator data, the preset ready-to-use CAD design drawings of the target cadastral land parcel can also be obtained, recognized and converted into corresponding 3D design scheme to be used as the building design scheme.

In addition to designing schemes using the building design method provided in the present disclosure, user can also import the design drawings made using CAD software, after obtaining the CAD design drawings of the target cadastral land parcel in CAD format, the building design device can recognize the CAD format design drawings and present them in 3D and convert them into 3D design scheme, and use the corresponding 3D design scheme as the building design scheme, this solves the problem of cross-platform and cross-system application, allowing users to conveniently edit and modify previous schemes.

It shall be understood that the sequence numbers of the steps in the embodiments described above don't indicate the order of execution seniority, and the order of executing the processes shall be determined by the functionality and internal logic without constituting any limitation to the implementation process of the embodiments in the present disclosure.

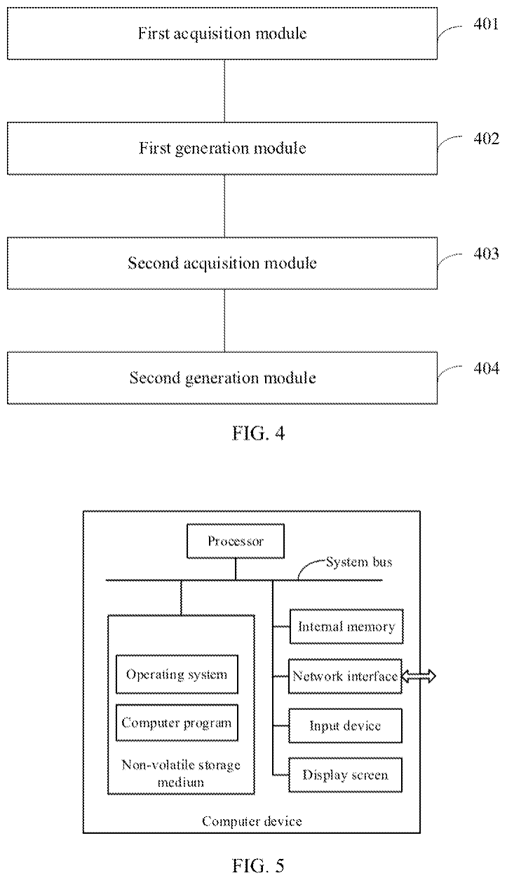

In one embodiment, a building design device used in building design system is provided, the building design system comprises cadastral land parcel evaluating device and scheme generating device, the building design device corresponds to the building design methods in the embodiments described above one by one. As shown in FIG. 4, the building design device comprises a first acquisition module 401, a first generation module 402, a second acquisition module 403 and a second generation module 404. Detailed description of the functional modules is as follow:

A first acquisition module 401, to obtain the location information of the target cadastral land parcel, and obtain the peripheral information of the target cadastral land parcel based on the location information, and the peripheral information comprises economy information, community information and transportation information;

A first generation module 402, to control the cadastral land parcel evaluating device to generate multiple data models of the target cadastral land parcel based on the economy information, community information and transportation information. The multiple data models comprise economic vitality model, economic value model, noise analysis model and viewshed analysis model;

A second acquisition module 403, to obtain the indicator data of the target cadastral land parcel, and the indicator data comprise floor area ratio, land area, city, land usage, functional composition and building density;

A second generation module 404, to control the scheme generating device to generate multiple building design schemes based on the data models and the indicator data.

In regard to the specific limitation on the building design device, refer to the limitation on the building design method described above, which is not further described herein. The modules in the building design device described above can be implemented through software, hardware or combination of the same in whole or in part. The modules described above can be embedded in or independent of the processor in the computer device in the form of hardware, or can be stored in the memory of the computer device in the form of software, so as to be called by the processor to perform the operations corresponding to such modules.

In one embodiment, a building design device is provided, which can be a computer device, of which the internal structure is as shown in FIG. 5. The building design device comprises processor, memory, network interface, display and input device connected through system bus. Where, the processor of the building design device is to provide computation and control ability. The memory of the building design device comprises non-volatile storage medium and internal memory. The non-volatile storage medium stores operating system and computer program. The internal memory provides environment for the operating system and the computer program in the non-volatile storage medium. The network interface of the building design device is for communication with the external server through network connection. A building design method is implemented when the computer program is executed by the processor.

In one embodiment, a building design device is provided, comprising memory, processor and computer program stored in the memory and runnable in the processor, and the steps as follow are implemented when the processor executes the computer program:

Obtain the location information of the target cadastral land parcel, and obtain the peripheral information of the target cadastral land parcel based on the location information, and the peripheral information comprises economy information, community information and transportation information;

Control the cadastral land parcel evaluating device to generate multiple data models of the target cadastral land parcel based on economy information, community information and transportation information, and the multiple data models comprise economic vitality model, economic value model, noise analysis model and viewshed analysis model;

Obtain the indicator data of the target cadastral land parcel, and the indicator data comprise floor area ratio, land area, city, land usage, functional composition and building density;

Control the scheme generating device to generate multiple building design schemes based on the data models and the indicator data.

In one embodiment, a storage medium readable by computer is provided, on which computer program is stored, the steps as follow are implemented when the computer program is executed by the processor:

Obtain the location information of the target cadastral land parcel, and obtain the peripheral information of the target cadastral land parcel based on the location information, and the peripheral information comprises economy information, community information and transportation information;

Control the cadastral land parcel evaluating device to generate multiple data models of the target cadastral land parcel based on economy information, community information and transportation information, and the multiple data models comprise economic vitality model, economic value model, noise analysis model and viewshed analysis model;

Obtain the indicator data of the target cadastral land parcel, and the indicator data comprise floor area ratio, land area, city, land usage, functional composition and building density;

Control the scheme generating device to generate multiple building design schemes based on the data models and the indicator data.

It can be understood by those of ordinary skill in the art that the whole or part of the process of the method in the above embodiment can be implemented by computer program instructing relevant hardware, the computer program can be stored in a non-volatile storage medium readable by computer, the execution of the computer program can comprise the processes in the embodiments of the methods described above. Where, any reference to memory, storage, database or other medium in the embodiments provided in this application may comprise both non-volatile memory and/or volatile memory. Non-volatile memory may comprise read-only memory (ROM), programmable ROM (PROM), electrically programmable ROM (EPROM), electrically erasable and programmable ROM (EEPROM) or flash memory. Volatile memory may comprise random access memory (RAM) or external cache memory. As illustration rather than limitation, RAM is available in many forms such as static RANI (SRAM), dynamic RANI (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

Those skilled in the art can clearly understand that, for the convenience of concise description, only examples of the functional units and modules described above are given, in actual application, such functions described above can be assigned to different functional units and modules for completion based on the need, i.e., the internal construction of the device can be divided into different functional units or modules to complete all or partial functions described above.

The embodiments described above are merely provided for description of the technical solutions of the present disclosure rather than limitation. Although the present disclosure has been described in detail in reference to the above embodiments, those of ordinary skill in the art shall understand that they can still modify the technical solutions described in the above embodiments, or conduct equivalent replacement to some technical features therein; but such modifications or replacements will not make the nature of the relevant technical solutions depart from the spirit and scope of the technical solution in the embodiments of the present disclosure, and shall be included in the protection scope of the present disclosure.

What is claimed is:

1. A building design method, wherein the building design method is used in building design system, the building design system comprises cadastral land parcel evaluating device and scheme generating device, comprising:
obtaining the location information of the target cadastral land parcel, and obtaining the peripheral information of the target cadastral land parcel based on the location information, the peripheral information comprises economy information, community information and transportation information;
based on the economy information, community information and transportation information, controlling the cadastral land parcel evaluating device to generate multiple data models of the target cadastral land parcel. The multiple data models comprise economic vitality model, economic value model, noise analysis model and viewshed analysis model;
obtaining the indicator data of the target cadastral land parcel, the indicator data comprise floor area ratio, land area, city, land usage, functional composition and building density;
controlling the scheme generating device to generate multiple building design schemes based on the data models and the indicator data.

2. The building design method according to claim 1, wherein after controlling the scheme generating device to generate multiple building design schemes based on the data models and the indicator data, the method further comprises:
obtaining user demand instruction, and determine the target design scheme from the multiple building design schemes based on the user demand instruction;
determining the display category of the target design scheme, and displaying the corresponding design content of the target design scheme based on the display category.

3. The building design method according to claim 2, wherein obtaining the indicator data of the target cadastral land parcel comprises:
obtaining the preset indicator data input by user;
obtaining the building design specification data of the city where the cadastral land parcel is located;
obtaining the indicator data by comparing the preset indicator data with the building design specification data.

4. The building design method according to claim 1, wherein the multiple building design schemes comprise:
An optimum scheme, of which the floor area ratio indicator, the density indicator, profit indicator and value indicator are the closest to the corresponding indicators of the indicator data among all schemes;
An optimum floor area ratio scheme, of which the floor area ratio is the closest to the floor area ratio corresponding to the indicator data among all schemes;
A maximum value scheme, of which the sales volume is the highest among all schemes;
A maximum profit scheme, of which the profit amount is the highest among all schemes;
A high-low configuration scheme, which has configuration of high-rise buildings and multi-floor buildings or villa among all schemes;
An ordinary layout scheme, of which the floor area ratio satisfies the floor area ratio corresponding to the indicator data, and of which the layout between the buildings is arranged from the most outside to the inside spirally based on the outline of the target cadastral land parcel;
A qualified floor area ratio scheme, of which the floor area ratio satisfies the floor area ratio corresponding to the indicator data and of which the layout spacing between the buildings are the most distant among all schemes;
A multi-side layout scheme, of which the floor area ratio satisfies the floor area ratio corresponding to the indicator data and of which the buildings are sequentially arranged from outside to inside firstly based on the outline of the cadastral land parcel among all schemes;
A building greening rate scheme, of which the floor area ratio satisfies the floor area ratio corresponding to the indicator data and which is the closest to the greening rate corresponding to the indicator data among all schemes.

5. The building design method according to claim 1, wherein after controlling the design device to generate multiple building design schemes based on the data models and the indicator data, the method further comprises:
determining a building design scheme from the multiple building design schemes as the target design scheme, and obtaining at least one comparison design scheme;
comparing and displaying based on the target design scheme and the comparison design scheme.

6. The building design method according to claim 5, wherein after the comparison and display based on the target design scheme and the comparison design scheme, the method further comprises:
conducting comparison based on the target design scheme and the comparison design scheme;
displaying the location information and current condition information of the target cadastral land parcel;
displaying pictures of the peripheral support facilities of the target cadastral land parcel based on the peripheral information of the target cadastral land parcel;
generating aerial view of design of the target cadastral land parcel based on the target design scheme and the peripheral information.

7. A building design device, wherein the building design device is used in the building design system, the building design system comprises cadastral land parcel evaluating device and scheme generating device, and the building design device comprises:
A first acquisition module, to obtain the location information of the target cadastral land parcel, and obtain the peripheral information of the target cadastral land parcel based on the location information, the peripheral information comprises economy information, community information and transportation information;
A first generation module, to control the cadastral land parcel evaluating device to generate multiple data models of the target cadastral land parcel based on the economy information, community information and transportation information. The multiple data models comprise economic vitality model, economic value model, noise analysis model and viewshed analysis model;
A second acquisition module, to obtain the indicator data of the target cadastral land parcel, the indicator data comprise floor area ratio, land area, city, land usage, functional composition and building density;
A second generation module, to control the scheme generating device to generate multiple building design schemes based on the data models and the indicator data.

8. A building design device, comprising a memory, a processor and a computer program stored in the memory and runnable in the processor, wherein the steps of the building design method described in claim 1 are realized when the processor executes the computer program.

9. The building design system, wherein comprising cadastral land parcel evaluating device, scheme generating device and the building design device according to claim 8.

10. A readable storage medium storing computer program, wherein the steps of the building design method described in claim 1 are implemented when the computer program is executed by the processor.
